(19) United States
(12) Patent Application Publication
(10) Pub. No.: US 2010/0133496 A1
(43) Pub. Date: Jun. 3, 2010

(54) Resistive random access memory

(75) Inventors: Chang-bum Lee, Seoul (KR); Chang-jung Kim, Yongin-si (KR); Dong-soo Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/588,274

(22) Filed: Oct. 9, 2009

(30) Foreign Application Priority Data
Dec. 2, 2008 (KR) 10-2008-0121277

(51) Int. Cl. H01L 47/00

(52) U.S. Cl. 257/2; 257/E47.001

(57) ABSTRACT

A RRAM may include a first electrode, a second electrode, and a memory resistant layer between the first and second electrodes, wherein the memory resistant layer may include a transition metal oxide doped with a metal having a high oxygen affinity. Because a RRAM includes a memory resistant layer doped with a material having a high oxygen affinity, the RRAM may be stably driven at higher temperatures.

### CROSS-REFERENCE TO RELATED APPLICATIONS

This application claims priority under 35 U.S.C. §119 to Korean Patent Application No. 10-2008-0121277, filed on Dec. 2, 2008, in the Korean Intellectual Property Office (KIPO), the entire contents of which are incorporated herein by reference.

### BACKGROUND

1. Field

Example embodiments relate to a resistive random access memory (RRAM), and more particularly, to a RRAM having an improved thermal stability by doping a material having a high oxygen affinity in a memory resistive layer for storing information, and a RRAM array.

2. Description of the Related Art

In general, a semiconductor memory includes multiple memory cells connected to one another in circuits. In dynamic random access memories (DRAMs) that are semiconductor memories, a unit memory cell generally includes one switch and one capacitor.

The DRAM exhibits a high integration and a fast operation speed. However, in the DRAM, all stored data is lost when power is off. Flash memories are an example of non-volatile memory devices capable of keeping stored data even when power is off. The flash memory is non-volatile, unlike a volatile memory, but has a low integration and a low operation speed, compared to those of the DRAM. The non-volatile memory devices include magnetic random access memories (MRAMs), ferroelectric random access memories (FRAMs), phase-change random access memories (PRAMs), and resistive random access memories (RRAMs).

The RRAM is a resistive memory that mainly uses a characteristic (a resistance conversion characteristic) where a resistance value varies according to the voltage of a transition metal oxide. The RRAM includes a memory resistant layer formed between upper and lower electrodes. The memory resistant layer is formed of a transition metal oxide and exhibits a variable resistance characteristic where a resistance value varies according to an applied voltage.

### SUMMARY

Example embodiments may include a RRAM exhibiting an improved thermal stability so as to be stably driven at a high temperature, and a RRAM array. Additional aspects will be set forth in part in the description which follows and, in part, will be apparent from the description, or may be learned by practice of example embodiments.

According to example embodiments, a RRAM may include a first electrode, a second electrode, and a memory resistant layer between the first and second electrodes, wherein the memory resistant layer may include a transition metal oxide doped with metal having a high oxygen affinity.

The metal may have an oxygen affinity higher than that of the transition metal of the transition metal oxide. The transition metal oxide may be Ni oxide and the metal may be at least one of Ta, Y, Mo, Mn, Al, and V. The transition metal oxide may be any one of Ni oxide, Ti oxide, Hf oxide, Zr oxide, Zn oxide, W oxide, Co oxide, and Nb oxide. The memory resistant layer may be doped with metal of about 0 to about 50 at %. The memory resistant layer may be doped with metal of about 0.5 to about 20 at %. The RRAM may further include a switch structure on the first electrode and an intermediate electrode between the switch structure and the memory resistant layer.

According to example embodiments, a RRAM array may include a plurality of first electrode lines in a first direction, a first switch structure on each of the first electrode lines, a first intermediate electrode on the first switch structure, a first memory resistant layer on the first intermediate electrode and formed of a transition metal oxide doped with metal having a high oxygen affinity, and a plurality of second electrode lines on the first memory resistant layer in a second direction.

The RRAM array may further include a second switch structure on the second electrode lines, a second intermediate electrode on the second switch structure, a second memory resistant layer on the second intermediate electrode and formed of a transition metal oxide doped with metal having a high oxygen affinity, and a plurality of third electrode lines on the second memory resistant layer in the first direction.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIGS. 1A and 1B illustrate the structure of a RRAM according to an example embodiment;

FIGS. 2A-2C are graphs for explaining the electrical characteristic of a RRAM according to a heat treatment process;

FIGS. 3A and 3B are graphs for explaining the electrical characteristic of a RRAM according to a heat treatment process; and

FIG. 4 is a perspective view showing the structure of a RRAM array according to an example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Reference will now be made in detail to example embodiments, examples of which are illustrated in the accompanying drawings, wherein like reference numerals refer to the like elements throughout. In this regard, example embodiments may have different forms and should not be construed as being limited to the descriptions set forth herein. Accordingly, example embodiments are merely described below, by referring to the figures, to explain aspects of the present description.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

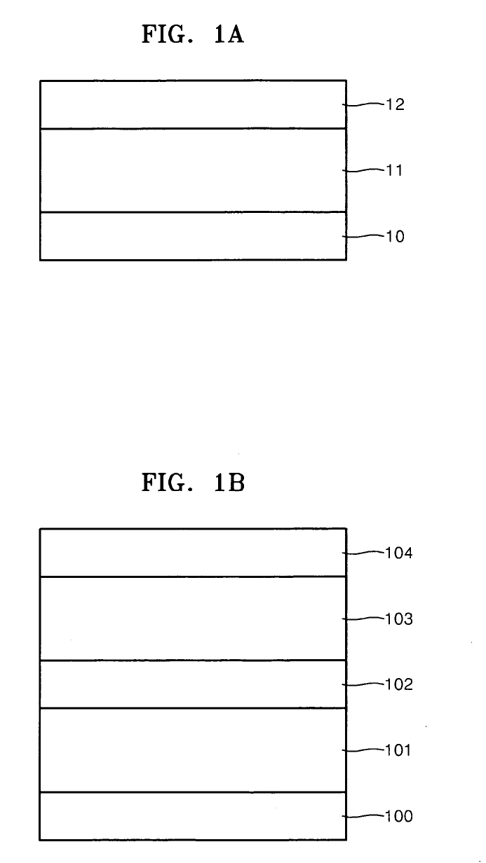

FIGS. 1A and 1B illustrate the structure of a RRAM according to an example embodiment. Referring to FIG. 1A, a memory resistant layer 11 may be formed on a first electrode 10 and a second electrode 12 may be formed on the memory resistant layer 11. The RRAM configured as above may include a switch device, which is shown in FIG. 1B. Referring to FIG. 1B, a switch structure 101, an intermediate electrode 102, a memory resistant layer 103, and a second electrode 104 are sequentially formed on and above a first electrode 100.

A material forming each layer of the RRAM shown in FIGS. 1A and 1B is described below. The first electrodes 10 and 100, the intermediate electrode 102, and the second electrodes 12 and 104 may be formed of a conductive material, for example, metal or a conductive metal oxide, used as an electrode material of a general semiconductor device. The switch structure 101 may be formed of a diode or a varistor. When the switch structure 101 has a diode structure, a silicon diode or oxide diode may be used for the switch structure 101.

The memory resistant layers 11 and 103 may be formed of a transition metal oxide exhibiting a variable resistance characteristic. Metal having a high oxygen affinity may be doped in the memory resistant layers 11 and 103. The transition metal oxide may include, for example, Ni oxide, Ti oxide, Hf oxide, Zr oxide, Zn oxide, W oxide, Co oxide, or Nb oxide. In detail, the transition metal oxide may include one of NiO, TiO₂, HfO, ZrO, ZnO, WO₃, CoO, and Nb₂O₅, or any combinations thereof. The doped metal has a high oxygen affinity.

Metal having an oxygen affinity higher than that of a transition metal of the transition metal oxide forming the memory resistant layers 11 and 103 may be used as the doping metal. The metal having a high oxygen affinity may be defined as a material having a low Gibbs free energy in an oxide state, when the metal forms an oxide by reacting to oxygen. For example, when the memory resistant layers 11 and 103 are formed of Ni oxide, at least one of Ta, Y, Mo, Mn, Al, and V having an oxygen affinity higher than that of Ni may be doped in the memory resistant layers 11 and 103. For example, Ta or Y exhibits a high oxygen affinity, with only one outermost electron.

In the memory resistant layers 11 and 103, metal having a high oxygen affinity may be doped at about 0 to about 50 at %, for example, at about 0.5 to about 20 at %, in the transition metal oxide. As the metal having a higher oxygen affinity is doped in the memory resistant layers 11 and 103, the memory resistant layers 11 and 103 may be prevented or retarded from losing the resistance conversion characteristic during a high temperature process so that the stability at a higher temperature may be improved.

In detail, when a high temperature process of about 300° C. is performed as a heat treatment on the switch structure 101, a thermally stable material needs to be used for the memory resistant layers 11 and 103. In particular, the above condition is applied when silicon diode is used for the switch structure 101. However, during the high temperature process, the variable resistance characteristic of the memory resistant layers 11 and 103 may be lost. The composition of a memory resistant layer that lost the variable resistance characteristic shows that the ingredient portion of oxygen has changed compared to the composition of a memory resistant layer. Thus, in order to control oxygen in the memory resistant layers 11 and 103, metal having a high oxygen affinity is doped in the memory resistant layers 11 and 103, thus improving thermal stability.

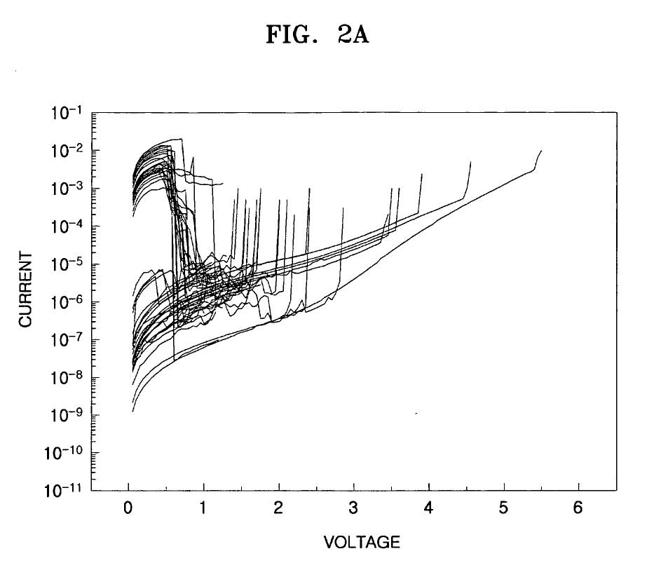

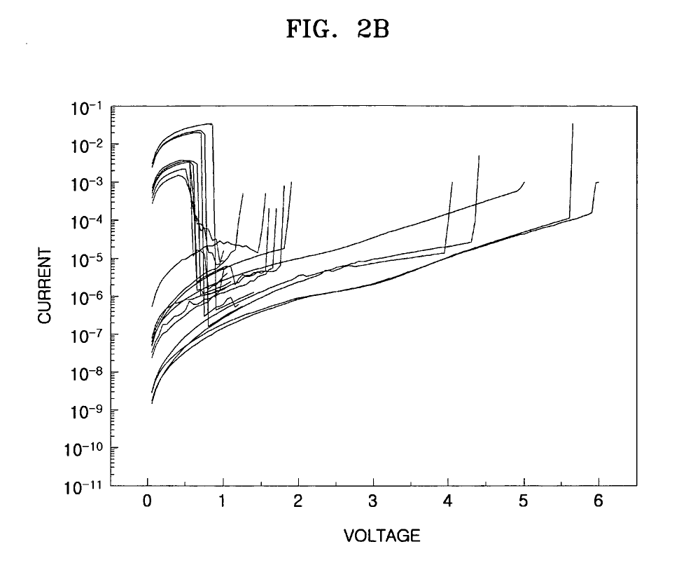

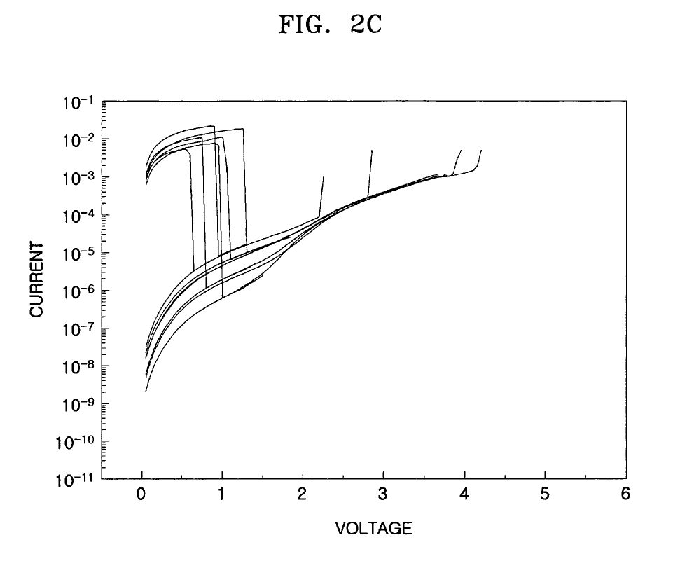

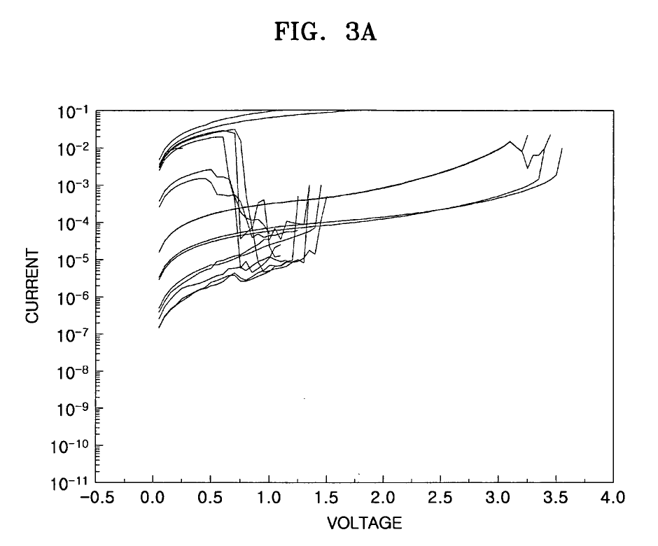

FIGS. 2A-2C are graphs for explaining the electrical characteristic of a RRAM according to a heat treatment process. In a specimen for a test, an electrode is formed of Pt, a memory resistant layer is formed of Ni oxide, and Ta is doped in the memory resistant layer at about 10 at %.

FIG. 2A shows a result of the test by repeatedly measuring a change in current to an applied voltage when a heat treatment process is not performed. Referring to FIG. 2A, the resistance conversion characteristic of the memory resistant layer appears when the heat treatment process is not performed.

FIG. 2B shows a result of the test by repeatedly measuring a change in current to an applied voltage when a heat treatment is performed at about 300° C. for about an hour. Referring to FIG. 2B, the resistance conversion characteristic of the memory resistant layer appears without change even when the heat treatment process is performed at a high temperature of about 300° C.

FIG. 2C shows a result of the test by repeatedly measuring a change in current to an applied voltage when a heat treatment is performed at about 300° C. for about an hour and then at about 600° C. for about an hour. Referring to FIG. 2C, the resistance conversion characteristic of the memory resistant layer appears without change even when the heat treatment processes are continuously performed at high temperatures of about 300° C. and about 600° C.

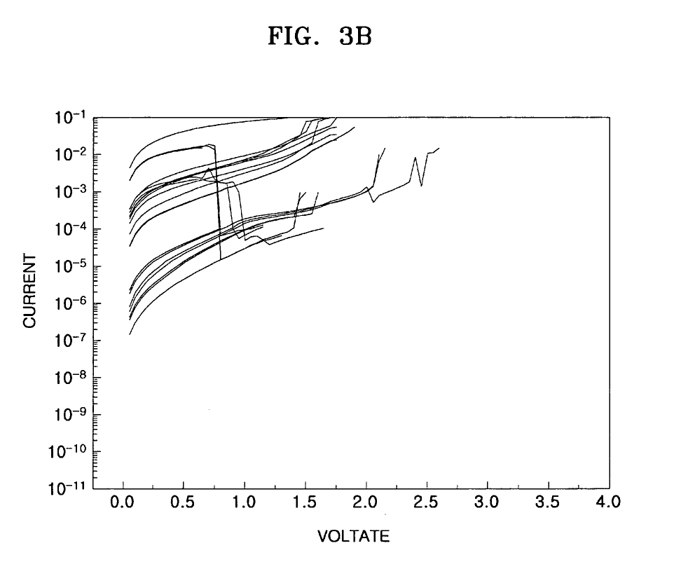

FIGS. 3A and 3B are graphs for explaining the electrical characteristic of a RRAM according to a heat treatment process. In a specimen for a test, an electrode is formed of Pt, a memory resistant layer is formed of Ni oxide, and Y is doped in the memory resistant layer at about 7 at %.

FIG. 3A shows a result of the test by repeatedly measuring a change in current to an applied voltage, when a heat treatment process is not performed on the specimen and the voltage is applied. Referring to FIG. 3A, the resistance conversion characteristic of the memory resistant layer appears when the heat treatment process is not performed.

FIG. 3B shows a result of the test by repeatedly measuring a change in current to an applied voltage, when a heat treatment is performed on the specimen at about 300° C. for about an hour. Referring to FIG. 3B, the resistance conversion characteristic of the memory resistant layer appears without change even when the heat treatment process is performed at a high temperature of about 300° C.

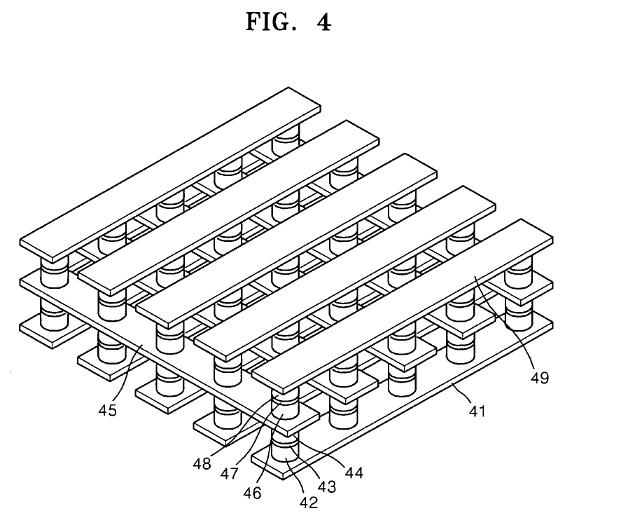

FIG. 4 is a perspective view showing the structure of a RRAM array according to an example embodiment. Referring to FIG. 4, the RRAM array may include a plurality of first electrode lines 41 formed in a first direction, a plurality of first switch structures 42 formed on the first electrode lines 41, a plurality of first intermediate electrodes 43, a plurality of first memory resistant layers 44, and a plurality of second electrode lines 45 in a second direction formed on the first memory resistant layers 44. A plurality of second switch structures 46, a plurality of second intermediate electrodes 47, a plurality of second memory resistant layers 48, and a plurality of third electrode lines 49 formed in the first direction are sequentially formed on and above the second electrode lines 45.

The first and second memory resistant layers 44 and 48 are formed of a transition metal oxide having a variable resistance characteristic. Metal having a high oxygen affinity may be doped in the first and second memory resistant layers 44 and 48. The doped metal may have an oxygen affinity higher than that of the transition metal of the transition metal oxide forming the first and second memory resistant layers 44 and 48. For example, when the first and second memory resistant layers 44 and 48 are formed of Ni oxide, at least one of Ta, Y, Mo, Mn, Al, and V having an oxygen affinity higher than that of Ni may be doped in the first and second memory resistant layers 44 and 48. The first and second memory resistant layers 44 and 48 may be doped with a metal having a high oxygen affinity at about 0-50 at %, in particular, at about 0.5-20 at %.

As described above, according to example embodiments, because a RRAM includes a memory resistant layer doped with a material having a high oxygen affinity, the RRAM may be stably driven at higher temperatures and a RRAM array may be provided.

It should be understood that example embodiments described therein should be considered in a descriptive sense only and not for purposes of limitation. Descriptions of features or aspects within each embodiment should typically be considered as available for other similar features or aspects in other example embodiments.

What is claimed is:

1. A RRAM comprising:
a first electrode;
a second electrode; and
a memory resistant layer between the first and second electrodes,
wherein the memory resistant layer includes a transition metal oxide doped with a metal having a high oxygen affinity.

2. The RRAM of claim 1, wherein the metal has an oxygen affinity higher than that of the transition metal of the transition metal oxide.

3. The RRAM of claim 2, wherein the transition metal oxide is Ni oxide and the metal is at least one of Ta, Y, Mo, Mn, Al, and V.

4. The RRAM of claim 1, wherein the transition metal oxide is any one of Ni oxide, Ti oxide, Hf oxide, Zr oxide, Zn oxide, W oxide, Co oxide, and Nb oxide.

5. The RRAM of claim 1, wherein the memory resistant layer is doped with metal of about 0 to about 50 at %.

6. The RRAM of claim 5, wherein the memory resistant layer is doped with metal of about 0.5 to about 20 at %.

7. The RRAM of claim 1, further comprising:
a switch structure on the first electrode; and
an intermediate electrode between the switch structure and the memory resistant layer.

8. A RRAM array comprising:
a plurality of first electrode lines in a first direction;
a first switch structure on each of the first electrode lines;
a first intermediate electrode on the first switch structure;
a first memory resistant layer on the first intermediate electrode and formed of a transition metal oxide doped with a metal having a high oxygen affinity; and
a plurality of second electrode lines on the first memory resistant layer in a second direction.

9. The RRAM array of claim 8, further comprising:
a second switch structure on the second electrode lines;
a second intermediate electrode on the second switch structure;
a second memory resistant layer on the second intermediate electrode and formed of a transition metal oxide doped with a metal having a high oxygen affinity; and
a plurality of third electrode lines on the second memory resistant layer in the first direction.

10. The RRAM array of claim 8, wherein the metal has an oxygen affinity higher than that of the transition metal of the transition metal oxide.

11. The RRAM array of claim 10, wherein the transition metal oxide is Ni oxide and the metal is at least one of Ta, Y, Mo, Mn, Al, and V.

12. The RRAM array of claim 8, wherein the transition metal oxide is any one of Ni oxide, Ti oxide, Hf oxide, Zr oxide, Zn oxide, W oxide, Co oxide, and Nb oxide.

13. The RRAM array of claim 8, wherein the first memory resistant layer is doped with metal of about 0 to about 50 at %.

14. The RRAM array of claim 13, wherein the first memory resistant layer is doped with metal of about 0.5 to about 20 at %.
